(19) United States
(12) Patent Application Publication
(10) Pub. No.: US 2026/0156873 A1
(43) Pub. Date: Jun. 4, 2026

(54) THIN FILM TRANSISTOR AND DISPLAY PANEL

(71) Applicant: WUHAN CHINA STAR OPTOELECTRONICS TECHNOLOGY CO., LTD., Wuhan, Hubei (CN)

(72) Inventors: Yinghui PAN, Wuhan, Hubei (CN); Wei CHEN, Wuhan, Hubei (CN); Fei AI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/705,502

(22) PCT Filed: Mar. 26, 2024
(86) PCT No.: PCT/CN2024/083709

§ 371 Date: Apr. 26, 2024

(30) Foreign Application Priority Data
Mar. 19, 2024 (CN) 202410317091.5

(51) Int. Cl. H10D 30/67; H10D 86/40; H10D 86/60

(52) U.S. Cl. CPC H10D 30/6757; H10D 30/6734; H10D 30/6736; H10D 30/6755; H10D 86/423; H10D 86/60

(57) ABSTRACT

The present application provides a thin film transistor and a display panel. An active layer of the thin film transistor includes at least two semiconductor layers stacked. Conductivity types of channel regions of adjacent two of the semiconductor layers are same. Doping concentrations of same elements in semiconductor materials of the adjacent two of the semiconductor layers are different. A homotypic heterostructure is formed after the adjacent two of the semiconductor layers contact, thereby improving a mobility of carriers.

### TECHNICAL FIELD

The present application relates to a technical field of display, in particular to a thin film transistor and a display panel.

### BACKGROUND

With the continuous development of display technologies, metal oxide thin film transistors (TFT) have been applied to next generation of flat panel displays because of their advantages, such as good uniformity in large areas and low fabrication temperature, thereby gradually replacing traditional amorphous silicon (a-Si) thin film transistors and low-temperature poly-silicon (LTPS) thin film transistors. However, with increasing requirements for mobilities of TFT devices in the display industry, current mobilities of metal oxides cannot meet those technical requirements. Therefore, how to improve the mobility of the metal oxides has become an urgent problem to be solved in the industry.

### SUMMARY

The present application provides a thin film transistor and a display panel to improve the mobility of metal oxides.

In order to solve above problem, technical solutions provided by the present application are as follows:

In a first aspect, an embodiment of the present application provides a thin film transistor including:
a substrate;
a source electrode, disposed on a side of the substrate;
an interlayer insulating layer, disposed on a side of the source electrode away from the substrate and exposing a part of the source electrode;
a first gate electrode, disposed on a side of the interlayer insulating layer away from the substrate;
a first gate insulating layer, disposed on a side of the first gate electrode away from the substrate and covering on a sidewall of the first gate electrode;
a drain electrode, disposed on a side of the first gate insulating layer away from the substrate; and
an active layer, disposed on a side of the first gate insulating layer away from the first gate electrode and covering on a sidewall of the drain electrode, a sidewall of the first gate insulating layer, and the source electrode exposed by the interlayer insulating layer, the active layer including at least two semiconductor layers stacked.

Conductivity types of channel regions of adjacent two of the semiconductor layers are same, and doping concentrations of same elements in semiconductor materials of the adjacent two of the semiconductor layers are different.

In a second aspect, an embodiment of the present application further provides a display panel including a thin film transistor, the thin film transistor includes:
a substrate;
a source electrode, disposed on a side of the substrate;
an interlayer insulating layer, disposed on a side of the source electrode away from the substrate and exposing a part of the source electrode;
a first gate electrode, disposed on a side of the interlayer insulating layer away from the substrate;
a first gate insulating layer, disposed on a side of the first gate electrode away from the substrate and covering on a sidewall of the first gate electrode;
a drain electrode, disposed on a side of the first gate insulating layer away from the substrate; and
an active layer, disposed on a side of the first gate insulating layer away from the first gate electrode and covering on a sidewall of the drain electrode, a sidewall of the first gate insulating layer, and the source electrode exposed by the interlayer insulating layer, the active layer including at least two semiconductor layers stacked.

Conductivity types of channel regions of adjacent two of the semiconductor layers are same, and doping concentrations of same elements in semiconductor materials of the adjacent two of the semiconductor layers are different.

### BRIEF DESCRIPTION OF THE DRAWINGS

To describe the technical solutions of the embodiments of the present application more clearly, the following briefly introduces the accompanying drawings used in the description of the embodiments of the present application. Apparently, the accompanying drawings described below illustrate only some exemplary embodiments of the present application, and persons skilled in the art may derive other drawings from the drawings without making creative efforts.

FIG. 1 is a cross-sectional structural schematic diagram of a thin film transistor provided by one embodiment of the present application.

FIG. 2 is a schematic diagram of an energy band of an active layer in shown FIG. 1.

FIG. 3 is another cross-sectional structural schematic diagram of the thin film transistor provided by another embodiment of the present application.

FIG. 4 is yet another cross-sectional structural schematic diagram of the thin film transistor provided by an embodiment of the present application.

### DETAILED DESCRIPTION

The following description of every embodiment with reference to the accompanying drawings is used to exemplify a specific embodiment which may be carried out in the present application. Directional terms mentioned in the present application, such as “top”, “bottom”, “front”, “back”, “left”, “right”, “inside”, “outside”, “side” etc., are only used with reference to orientations of the accompanying drawings. Therefore, the used directional terms are intended to illustrate, but not to limit, the present application. In the accompanying drawings, units with similar structures are indicated by a same number. In the accompanying drawings, thicknesses of some layers and regions are exaggerated for clarity of understanding and ease of description. The dimension and thickness of each of the elements in the accompanying drawings are arbitrarily shown, but the present application is not limited thereto.

In view of a fact that a mobility of metal oxides in the prior art can not meet mobility requirements of the display industry for thin film transistor devices, inventors of the present application found in research that the thin film transistors in the prior art include a substrate and an active layer disposed on a side of the substrate, the active layer is formed by a single layer of the metal oxide, and the mobility of the metal oxide in the active layer is lower, which cannot meet the mobility requirements of the display industry for the thin film transistor devices.

Therefore, the present application provides a thin film transistor and a display panel to solve above problem.

In one embodiment, the embodiment of the present application provides a thin film transistor, including:
a substrate;
a source electrode, disposed on a side of the substrate;
an interlayer insulating layer, disposed on a side of the source electrode away from the substrate and exposing a part of the source electrode;
a first gate electrode, disposed on a side of the interlayer insulating layer away from the substrate;
a first gate insulating layer, disposed on a side of the first gate electrode away from the substrate and covering on a sidewall of the first gate electrode;
a drain electrode, disposed on a side of the first gate insulating layer away from the substrate; and
an active layer, disposed on a side of the first gate insulating layer away from the first gate electrode and covering on a sidewall of the drain electrode, a sidewall of the first gate insulating layer, and the source electrode exposed by the interlayer insulating layer, the active layer including at least two semiconductor layers stacked.

Conductivity types of channel regions of adjacent two of the semiconductor layers are same, and doping concentrations of same elements in semiconductor materials of the adjacent two of the semiconductor layers are different.

In one embodiment, the active layer includes a first semiconductor layer and a second semiconductor layer stacked. Band gaps of the first semiconductor layer and the second semiconductor layer are different.

In one embodiment, the active layer includes a first semiconductor layer and a second semiconductor layer stacked. A material of the first semiconductor layer is indium zinc oxide (IZO), and a material of the second semiconductor layer is indium gallium zinc oxide (IGZO). A doping concentration of indium element in the first semiconductor layer is different from a doping concentration of indium element in the second semiconductor layer.

In one embodiment, a thickness of the first semiconductor layer is greater than a thickness of the second semiconductor layer.

In one embodiment, the active layer includes a first semiconductor layer and a second semiconductor layer stacked. Materials of the first semiconductor layer and the second semiconductor layer are IGZO. A doping concentration of indium element in the first semiconductor layer is different from a doping concentration of indium element in the second semiconductor layer.

In one embodiment, a thickness of the first semiconductor layer is less than a thickness of the second semiconductor layer.

In one embodiment, the active layer further includes a third semiconductor layer located on a side of the second semiconductor layer away from the first semiconductor layer. A material of the third semiconductor layer is IGZO. A doping concentration of indium element in the third semiconductor layer is different from the doping concentration of indium element in the second semiconductor layer.

In one embodiment, the doping concentration of indium element in the second semiconductor layer is greater than the doping concentration of indium element in the third semiconductor layer.

In one embodiment, the active layer includes a first semiconductor layer and a second semiconductor layer stacked and a third semiconductor layer located on a side of the second semiconductor layer away from the first semiconductor layer. Band gaps of the third semiconductor layer and the second semiconductor layer are different. Materials of the first semiconductor layer, the second semiconductor layer, and the third semiconductor layer are ZnO, AlZnO, and YZnO, respectively.

In one embodiment, the thin film transistor further includes:
a second gate insulating layer, disposed on a side of the active layer away from the first gate insulating layer; and
a second gate electrode, disposed on a side of the second gate insulating layer away from the active layer.

In one embodiment, the drain electrode is a transparent electrode.

In one embodiment, materials of the source electrode and the drain electrode include metal materials with reducibility.

In one embodiment, the embodiment of the present application further provides a display panel including the thin film transistor of one of the aforementioned embodiments.

In the thin film transistor and the display panel provided by the embodiments of the present application, the thin film transistor includes the substrate and the active layer disposed on the side of the substrate. The active layer includes at least two semiconductor layers stacked. The conductivity types of the channel regions of the adjacent two of the semiconductor layers are same. The doping concentrations of same elements in the semiconductor materials of the adjacent two of the semiconductor layers are different. In this way, a homotypic heterostructure will be formed after the adjacent two of the semiconductor layers contact. An electric potential barrier will be formed at a heterojunction interface, so that concentrations of electrons and holes are different, and a band gap and a conductivity at the heterojunction interface are different from those of the semiconductor layers adjacent to the heterojunction interface. An energy of the electrons turning into free electrons near the heterojunction interface will be reduced, and then an energy band near the heterojunction interface will bend downward. In that situation, a “depression” will be generated at a bending place of the energy band, and the electrons will gather here, so that a high-concentration electron region is formed, and a scattering effect of donor impurities on the electrons will be reduced, thereby improving the mobility of carriers.

The thin film transistor and the display panel of the present application will be described in detail below with reference to the accompanying drawings in particular manner.

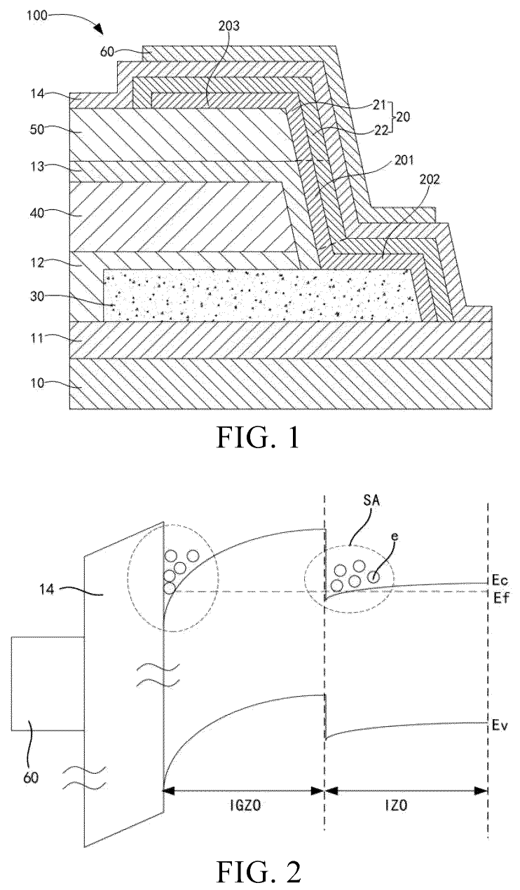

In one embodiment, please refer to FIG. 1 and FIG. 2, FIG. 1 is a cross-sectional structural schematic diagram of a thin film transistor provided by one embodiment of the present application. FIG. 2 is a schematic diagram of an energy band of an active layer shown in FIG. 1. Referring to FIG. 1, an active layer 20 includes a first semiconductor layer 21 and a second semiconductor layer 22 stacked. Energy band structures of semiconductor materials of the first semiconductor layer 21 and the second semiconductor layer 22 are different. For example, the band gaps of the first semiconductor layer 21 and the second semiconductor layer 22 are different. Alternatively, the material of the first semiconductor layer 21 is IZO, and the material of the second semiconductor layer 22 is IGZO. Both IZO and IGZO are N-type semiconductor layer materials. That is, conductivity types of the channel regions of IZO and IGZO are the same. Moreover, a lattice matching between IZO and IGZO is high and their energy band structures are different. For example, band gaps of IZO and IGZO are different. A homotypic heterostructure will be formed after IZO and IGZO contact. An electric potential barrier will be formed at a heterojunction interface, so that concentrations of electrons and holes are different, and a band gap and a conductivity at the heterojunction interface are different from those of the semiconductor layers adjacent to the heterojunction interface. An energy of the electrons turning into free electrons near the heterojunction interface will be reduced, and then an energy band near the heterojunction interface will bend downward. In that situation, a “depression” will be generated at a bending place of the energy band, and the electrons will gather here, so that a high-concentration electron region is formed, and a scattering effect of donor impurities on the electrons will be reduced, thereby improving the mobility of carriers.

In one embodiment, when the material of the first semiconductor layer 21 is IZO, and the material of the second semiconductor layer 22 is IGZO, a doping concentration of indium element in the first semiconductor layer 21 is different from a doping concentration of indium element in the second semiconductor layer 22. Additionally, the band gap of the first semiconductor layer 21 and the band gap of the second semiconductor layer 22 can be adjusted, and an adjustment space of the band gaps of the first semiconductor layer 21 and the second semiconductor layer 22 can be increased, so that the homotypic heterostructure can be easily formed at a contact interface between the first semiconductor layer 21 and the second semiconductor layer 22, thereby further improving the mobility of carriers.

Other structures of the thin film transistor 100 will be described in detail as follows.

Referring to FIG. 1 again, the thin film transistor 100 further includes a source electrode 30, a first gate electrode 40, a first gate insulating layer 13, and a drain electrode 50. The source electrode 30 is disposed on a side of the substrate 10. The first gate electrode 40 is disposed on a side of the source electrode 30 away from the substrate 10. The first gate insulating layer 13 is disposed on a side of the first gate electrode 40 away from the substrate 10 and covering on a sidewall of the first gate electrode 40. The drain electrode 50 is disposed on a side of the first gate insulating layer 13 away from the substrate 10. The active layer 20 is disposed on a side of the first gate insulating layer 13 away from the first gate electrode 40 and connected to the source electrode 30 and the drain electrode 50.

Alternatively, a buffer layer 11 is further disposed between the substrate 10 and the source electrode 30. The buffer layer 11 can prevent unwanted impurities or pollutants (such as moisture, oxygen, etc.) from spreading from the substrate 10 to devices that may be damaged by these impurities or pollutants. At the same time, the buffer layer 11 further provides a flat top surface. The buffer layer 11 may be silicon nitride (SiNx), silicon oxide (SiOx), or a stack layer of silicon nitride and silicon oxide.

The source electrode 30 is disposed on a side of the buffer layer 11 away from the substrate 10. Alternatively, the material of the source electrode 30 includes a metal conductive material with strong reducibility. For example, the source electrode 30 is a stacked layer formed of titanium, aluminum, and titanium. Titanium has a stronger reducibility capable of capturing oxygen atoms of the active layer 20 and reducing oxygen vacancies, so that a heavily doped region is formed on a surface of the active layer 20 to form a good ohmic contact with the source electrode 30. Certainly, the source electrode 30 may further be formed of other metallic conductive materials, such as copper, molybdenum, etc.

The thin film transistor 100 further includes an interlayer insulating layer 12. The interlayer insulating layer 12 covers a part of the source electrode 30 and the buffer layer 11 and exposes a part of the source electrode 30. The interlayer insulating layer 12 may be silicon nitride (SiNx), silicon oxide (SiOx), or the stack layer of silicon nitride and silicon oxide.

The first gate electrode 40 is disposed on a side of the interlayer insulating layer 12 away from the substrate 10. The first gate electrode 40 further exposes the source electrode 30 not covered by the interlayer insulating layer 12. That is, the sidewall of the first gate electrode 40 is flush with a sidewall of the first interlayer insulating layer 12 to form an inclined surface. Alternatively, the first gate electrode 40 is a single layer or a stacked layer of metals such as Mo, Al, Cu, Ti, etc., or alloys.

The first gate insulating layer 13 is disposed on the side of the first gate electrode 40 away from the substrate 10 and covers on the sidewall of the first gate electrode 40. Specifically, the first gate insulating layer 13 covers on an upper surface of the side of the first gate electrode 40 away from the substrate 10, and extends from the upper surface of the first gate electrode 40 to the sidewall of the first gate electrode 40 and a sidewall of the interlayer insulating layer 12. The first gate insulating layer 13 may be silicon nitride (SiNx), silicon oxide (SiOx), or the stack layer of silicon nitride and silicon oxide.

The drain electrode 50 is disposed on the side of the first gate insulating layer 13 away from the substrate 10. A sidewall of the drain electrode 50 is flush with a part of the first gate insulating layer 13 covering the sidewall of the first gate electrode 40 and the interlayer insulating layer 12. Alternatively, a material of the drain electrode 50 is the same as the material of the source electrode 30. That is, the material of the drain electrode 50 includes the metal conductive material with strong reducibility. For example, the drain electrode 50 is a stacked layer formed of titanium, aluminum, and titanium. Titanium has stronger reducibility capable of capturing oxygen atoms of the active layer 20 and reducing oxygen vacancies, so that a heavily doped region is formed on the surface of the active layer 20 to form a good ohmic contact with the drain electrode 50.

Certainly, in other embodiments, the drain electrode 50 may further be formed of other metallic conductive materials, such as copper, molybdenum, etc. Alternatively, the drain electrode 50 may further be formed of a transparent conductive material, such as ITO. The drain electrode 50 is formed of the transparent conductive material, which may improve a transmittance of light rays. When the thin film transistor 100 is applied to the display panel, a transmittance of the display panel may be improved.

The active layer 20 is disposed on the side of the first gate insulating layer 13 away from the first gate electrode 40 and connected to the source electrode 30 and the drain electrode 50. Specifically, the active layer 20 covers on an upper surface of a side of the drain electrode 50 away from the substrate 10, and extends from the upper surface of the drain electrode 50 to the sidewall of the drain electrode 50, a sidewall of the first gate insulating layer 13, the upper surface of the side of the source electrode 30 away from the substrate 10, and a sidewall of the source electrode 30. More specifically, the active layer 20 includes a channel 201, a source doped region 202, and a drain doped region 203. The source doped region 202 and the drain doped region 203 are disposed at opposite sides of the channel 201. The source doped region 202 is connected to the source electrode 30, and the drain doped region 203 is connected to the drain electrode 50. The channel 201 is corresponding to the sidewall of the first gate electrode 40. That is, the source doped region 202 covers the upper surface of the source electrode 30 and the sidewall of the source electrode 30, the drain doped region 203 covers the upper surface of the drain electrode 50 and the sidewall of the drain electrode 50, and the channel 201 covers the sidewall of the first gate insulating layer 13, thereby forming a vertical channel 201 and reducing an occupied area of the thin film transistor 100. When the thin film transistor 100 is applied to the display panel, the display panel with high resolution and high pixel density can be realized. A width of the vertical channel 201 depends on a thickness of the first gate electrode 40, thereby achieving a larger aspect ratio of the channel 201 of the thin film transistor 100.

In one embodiment, the thin film transistor 100 further includes a second gate insulating layer 14 and a second gate electrode 60. The second gate insulating layer 14 is disposed on a side of the active layer 20 away from the first gate insulating layer 13. The second gate electrode 60 is disposed on a side of the second gate insulating layer 14 away from the active layer 20.

Specifically, the second gate insulating layer 14 covers a part of the upper surface of the drain electrode 50, the drain doped region 203 of the active layer 20, the channel 201 of the active layer 20, the source doped region 202 of the active layer 20, and a part of the buffer layer 11 sequentially. Alternatively, the second gate insulating layer 14 may be silicon nitride (SiNx), silicon oxide (SiOx), or the stack of silicon nitride and silicon oxide.

The second gate electrode 60 is disposed on the side of the second gate insulating layer 14 away from the active layer 20 to form a double-gate structure. A double gate control can provide strong gate control capability, which is more suitable for devices with short channels 201. The first gate electrode 40 and the second gate electrode 60 of the double-gate structure may have an equal potential or may not have an equal potential.

Alternatively, referring to FIG. 1 again, the second semiconductor layer 22 is located on a side of the first semiconductor layer 21 away from the first gate electrode 40, and the first semiconductor layer 21 is located on a side of the second semiconductor layer 22 away from the second gate electrode 60. A thickness of the first semiconductor layer 21 is greater than a thickness of the second semiconductor layer 22, so as to ensure that the active layer 20 has a better electrical property. It should be noted that due to the material of the second semiconductor layer 22 being IGZO, a climbing performance of IGZO is better than that of IZO. On the premise that no disconnection occurs and an overall thickness of the active layer 20 is fixed, IGZO with a smaller thickness can be provided, so that IZO with a larger thickness can be provided, thereby ensuring that the first semiconductor layer 21 will not have disconnection during climbing, and further ensuring an electrical performance of the active layer 20 formed by the first semiconductor layer 21 and the second semiconductor layer 22.

Next, taking the material of the active layer 20 as IZO and IGZO as an example, the effects of improving the mobility of the carriers of the embodiment of the present application is further explained by using schematic diagram of the energy bands of IZO and IGZO.

Referring to FIG. 2, Ec represents a conduction band of IZO and IGZO, Ev represents a valence band of IZO and IGZO, and Ef represents a Fermi energy level. It can be seen from FIG. 2 that a homotypic heterostructure will be formed when IZO and IGZO contact. An electric potential barrier will be formed at a heterojunction interface, so that concentrations of electrons and the holes are different, and a band gap and a conductivity at the heterojunction interface are different from those of the semiconductor layers adjacent to the heterojunction interface. An energy of the electrons turning into free electrons near the heterojunction interface will be reduced, and then an energy band near the heterojunction interface will bend downward. In that situation, the “depression” will be generated at a bending place of the energy band, and the electrons e will gather here, so that a high-concentration electron region SA is formed, and a scattering effect of donor impurities on the electrons will be reduced, thereby improving the mobility of carriers.

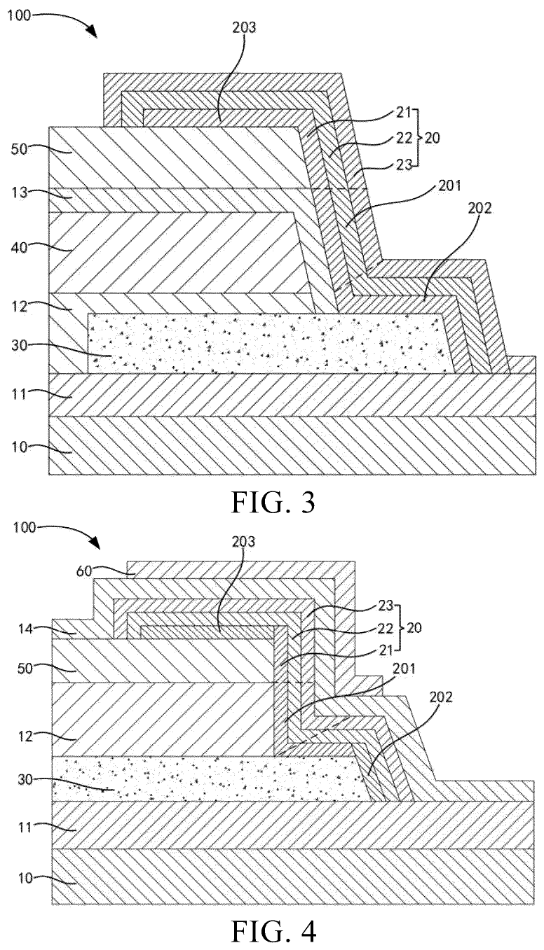

In one embodiment, referring to FIG. 1 to FIG. 3, FIG. 3 is another cross-sectional structural schematic diagram of the thin film transistor 100 provided by another embodiment of the present application. Different from the above embodiments, the active layer 20 includes three semiconductor layers. For example, the active layer 20 includes the first semiconductor layer 21, the second semiconductor layer 22, and a third semiconductor layer 23 stacked.

Specifically, referring to FIG. 3, the second semiconductor layer 22 is located on the side of the first semiconductor layer 21 away from the first gate electrode 40, and the third semiconductor layer 23 is located on a side of the second semiconductor layer 22 away from the first semiconductor layer 21. Alternatively, the materials of the first semiconductor layer 21 and the second semiconductor layer 22 are both IGZO. The doping concentration of the indium element in the first semiconductor layer 21 is different from the doping concentration of the indium element in the second semiconductor layer 22, so that the energy band structures of the first semiconductor layer 21 and the second semiconductor layer 22 are different, and the homotypic heterostructure is formed at the contact interface between the first semiconductor layer 21 and the second semiconductor layer 22. A material of the third semiconductor layer 23 is also IGZO. A doping concentration of indium element of the third semiconductor layer 23 is different from the doping concentration of the indium element in the second semiconductor layer 22, so that the energy band structures of the second semiconductor layer 22 and the third semiconductor layer 23 are different, and a homotypic heterostructure is formed at a contact interface between the third semiconductor layer 23 and the second semiconductor layer 22. The doping concentration of the indium element in the first semiconductor layer 21 is less than the doping concentration of the indium element in the second semiconductor layer 22, and the doping concentration of the indium element in the third semiconductor layer 23 is also less than the doping concentration of the indium element in the second semiconductor layer 22, so that an energy at which the electrons near the interface with a low doping concentration become free electrons is reduced, the energy band is bent, the electrons gather at the interface to form a high-concentration electron region, and the scattering effect of donor impurities on the electrons is reduced, thereby improving the mobility of the carriers.

Alternatively, the thickness of the first semiconductor layer 21 is less than the thickness of the second semiconductor layer 22, and a thickness of the third semiconductor layer 23 is also less than the thickness of the second semiconductor layer 22. The thickness of the first semiconductor layer 21 and the thickness of the third semiconductor layer 23 range from 5 nm to 15 nm, and the thickness the second semiconductor layer 22 ranges from 20 nm to 30 nm. For example, when the thickness of the first semiconductor layer 21 is 10 nm, the thickness of the second semiconductor layer 22 is 25 nm, and the thickness of the third semiconductor layer 23 is 10 nm, the mobility of the channel 201 of the active layer 20 is optimal.

Alternatively, in some embodiments, the thin film transistor 100 in this embodiment may further include the second gate electrode 60 and the second gate insulating layer 14 as in the aforementioned embodiments to achieve double-gate driving. Similarly, the double-gate second gate electrode 60 insulating layer is disposed on a side of the active layer 20 away from the first gate electrode 40. The second gate electrode 60 is disposed on the side of the second gate insulating layer 14 away from the active layer 20. The second semiconductor layer 22 of the active layer 20 is located on a side of the third semiconductor layer 23 away from the second gate electrode 60.

It should be noted that in some other embodiments, when the active layer 20 includes three semiconductor layers, the material of the first semiconductor layer 21 is IZO, the material of the second semiconductor layer 22 is IGZO, and the material of the third semiconductor layer 23 is IGZO. The doping concentration of the indium element in the third semiconductor layer 23 is different from the doping concentration of the indium element in the second semiconductor layer 22, so that the purpose of improving the mobility of the carriers in the above embodiments can also be achieved. When the active layer 20 includes two semiconductor layers, the material of the first semiconductor layer 21 is IGZO, and the material of the second semiconductor layer 22 is IGZO. The doping concentration of the indium element in the first semiconductor layer 21 is different from the doping concentration of the indium element in the second semiconductor layer 22. In this time, the purpose of improving the mobility of the carriers in the above embodiments can also be achieved. For other explanations, please refer to the above embodiments and will not be repeated here.

In one embodiment, referring to FIG. 1 to FIG. 4, FIG. 4 is another cross-sectional structural schematic diagram of the thin film transistor 100 provided by an embodiment of the present application. Different from the above-described embodiments, the materials of the three semiconductor layers of the active layer 20 is different from the above-described embodiments. Specifically, the materials of the first semiconductor layer 21, the second semiconductor layer 22, and the third semiconductor layer 23 are ZnO, AlZnO, and YZnO, respectively. ZnO, AlZnO, and YZnO are all N-type semiconductor materials, which have a high lattice matching and different energy band structures. For example, band gaps of ZnO and AlZnO are different, and band gaps of AlZnO and YZnO are also different. That is, the band gaps of the first semiconductor layer 21 and the second semiconductor layer 22 are different, and the band gaps of the third semiconductor layer 23 and the second semiconductor layer 22 are different, so that the homotypic heterostructure is formed at the contact interfaces between the first semiconductor layer 21 and the second semiconductor layer 22, and the homotypic heterostructure is also formed at the contact interface between the third semiconductor layer 23 and the second semiconductor layer 22, thereby improving the mobility of the carriers.

Alternatively, a doping concentration of zinc element in the first semiconductor layer 21 is different from a doping concentration of zinc element in the second semiconductor layer 22. Additionally, the band gap of the first semiconductor layer 21 and the band gap of the second semiconductor layer 22 can be adjusted, and the adjustment space of the band gaps of the first semiconductor layer 21 and the second semiconductor layer 22 can be increased, so that the homotypic heterostructure can be easily formed at the contact interface between the first semiconductor layer 21 and the second semiconductor layer 22, thereby further improving the mobility of carriers. Accordingly, a doping concentration of zinc element in the third semiconductor layer 23 is different from the doping concentration of the zinc element in the second semiconductor layer 22. Additionally, the band gap of the third semiconductor layer 23 and the band gap of the second semiconductor layer 22 can be adjusted, and an adjustment space of the band gap width of the third semiconductor layer 23 and the second semiconductor layer 22 can be increased, thereby the homotypic heterostructure can be easily formed at a contact interface between the third semiconductor layer 23 and the second semiconductor layer 22, thereby further improving the mobility of the carriers.

In addition, further different from the above embodiments, referring to FIG. 4, in the thin film transistor 100 of the present embodiment, the thin film transistor 100 includes one gate electrode, that is, the second gate electrode 60. The second gate electrode 60 is located on the side of the second gate insulating layer 14 away from the active layer 20. That is, no gate electrode is provided between the source electrode 30 and the drain electrode 50. Additionally, the second semiconductor layer 22 is located on the side of the third semiconductor layer 23 away from the second gate electrode 60, and the first semiconductor layer 21 is located on a side of the second semiconductor layer 22 away from the third semiconductor layer 23. The material of the third semiconductor layer 23 is YZnO, thereby reducing interface defects between the first semiconductor layer 21 and the second gate insulating layer 14, and between the second semiconductor layer 22 and the second gate insulating layer 14, thereby improving an electrical stability of the thin film transistor 100.

It should be noted that in other embodiments, when the active layer 20 includes three semiconductor layers, and the materials of the three semiconductor layers are ZnO, AlZnO, and YZnO, respectively, the thin film transistor 100 can also be driven by the double-gate driving. That is, the thin film transistor 100 can also include the first gate electrode 40 disposed between the source electrode 30 and the drain electrode 50 in the aforementioned embodiments. Moreover, when the thin film transistor 100 includes one gate electrode, the gate electrode may also be disposed between the source electrode 30 and the drain electrode 50. That is, the thin film transistor 100 includes the first gate electrode 40 in the aforementioned embodiments. However, at this time, the semiconductor layer formed by YZnO needs to be located between the semiconductor layer formed by ZnO and AlZnO and the first gate electrode 40, thereby reducing interface defects between ZnO and the gate insulating layer, and between AlZnO and the gate insulating layer. For other explanations, please refer to the above embodiments and will not be repeated here.

Based on the same inventive concept, the present application further provides a display panel including the thin film transistor 100 of one of the aforementioned embodiments.

As can be seen from the above embodiments:

The present application provides the thin film transistor and the display panel. The active layer of the thin film transistor covers on the sidewall of the drain electrode, the side wall of the first gate insulating layer, and the source electrode exposed by the interlayer insulating layer to form the vertical channel, thereby reducing the occupied area of the thin film transistor, and enabling the channel of the thin film transistor to achieve a larger aspect ratio. The active layer includes at least two semiconductor layers stacked. The conductive types of the channel regions of the adjacent two of the semiconductor layers are the same. The doping concentration of the same element in the semiconductor material of the adjacent two semiconductor layers is different. Therefore, the homotypic heterostructure will be formed when the adjacent two of the semiconductor layers contact. The electric potential barrier will be formed at the heterojunction interface, so that the concentrations of electrons and holes are different, and the band gap and the conductivity at the heterojunction interface are different from those of the semiconductor layers adjacent to the heterojunction interface. The energy of the electrons turning into free electrons near the heterojunction interface will be reduced, and then the energy band near the heterojunction interface will bend downward. At this time, the “depression” will be generated at a bending place of the energy band, and the electrons will gather here, so that the high-concentration electron region is formed, and the scattering effect of donor impurities on the electrons will be reduced, thereby improving the mobility of the carriers.

In the foregoing embodiments, the descriptions of the embodiments have their respective focuses. For a part that is not described in detail in an embodiment, reference may be made to related descriptions in other embodiments.

The embodiments of the present application are described in detail above. The principles and implementations of the present application are described in this specification by using specific examples. The description about the foregoing embodiments is merely provided to help understand the method and core ideas of the present application. Persons of ordinary skill in the art should understand that they may still make modifications to the technical solutions described in the foregoing embodiments or make equivalent replacements to some or all technical features thereof, without departing from the scope of the technical solutions of the embodiments of the present application.

What is claimed is:

1. A thin film transistor, comprising:
a substrate;
a source electrode, disposed on a side of the substrate;
an interlayer insulating layer, disposed on a side of the source electrode away from the substrate and exposing a part of the source electrode;
a first gate electrode, disposed on a side of the interlayer insulating layer away from the substrate;
a first gate insulating layer, disposed on a side of the first gate electrode away from the substrate and covering on a sidewall of the first gate electrode;
a drain electrode, disposed on a side of the first gate insulating layer away from the substrate; and
an active layer, disposed on a side of the first gate insulating layer away from the first gate electrode and covering on a sidewall of the drain electrode, a sidewall of the first gate insulating layer, and the source electrode exposed by the interlayer insulating layer, wherein the active layer comprises at least two semiconductor layers stacked;
wherein conductivity types of channel regions of adjacent two of the semiconductor layers are same, and doping concentrations of same elements in semiconductor materials of the adjacent two of the semiconductor layers are different.

2. The thin film transistor according to claim 1, wherein the active layer comprises a first semiconductor layer and a second semiconductor layer stacked, and band gaps of the first semiconductor layer and the second semiconductor layer are different.

3. The thin film transistor according to claim 1, wherein the active layer includes a first semiconductor layer and a second semiconductor layer stacked, a material of the first semiconductor layer is indium zinc oxide (IZO), a material of the second semiconductor layer is indium gallium zinc oxide (IGZO), and a doping concentration of indium element in the first semiconductor layer is different from a doping concentration of indium element in the second semiconductor layer.

4. The thin film transistor according to claim 3, wherein a thickness of the first semiconductor layer is greater than a thickness of the second semiconductor layer.

5. The thin film transistor according to claim 1, wherein the active layer comprises a first semiconductor layer and a second semiconductor layer stacked, materials of the first semiconductor layer and the second semiconductor layer are IGZO, and a doping concentration of indium element in the first semiconductor layer is different from a doping concentration of indium element in the second semiconductor layer.

6. The thin film transistor according to claim 5, wherein a thickness of the first semiconductor layer is less than a thickness of the second semiconductor layer.

7. The thin film transistor according to claim 5, wherein the active layer further comprises a third semiconductor layer located on a side of the second semiconductor layer away from the first semiconductor layer, a material of the third semiconductor layer is IGZO, and a doping concentration of indium element in the third semiconductor layer is different from the doping concentration of the indium element in the second semiconductor layer.

8. The thin film transistor according to claim 7, wherein the doping concentration of indium element in the second semiconductor layer is greater than the doping concentration of indium element in the third semiconductor layer.

9. The thin film transistor according to claim 1, wherein the active layer comprises a first semiconductor layer and a second semiconductor layer stacked and a third semiconductor layer located on a side of the second semiconductor layer away from the first semiconductor layer, band gaps of the third semiconductor layer and the second semiconductor layer are different, and materials of the first semiconductor layer, the second semiconductor layer, and the third semiconductor layer are zinc oxide ZnO, AlZnO, and YZnO, respectively.

10. The thin film transistor according to claim 1, further comprising:
a second gate insulating layer, disposed on a side of the active layer away from the first gate insulating layer; and
a second gate electrode, disposed on a side of the second gate insulating layer away from the active layer.

11. The thin film transistor according to claim 10, wherein the drain electrode is a transparent electrode.

12. The thin film transistor according to claim 10, wherein materials of the source electrode and the drain electrode comprise metal materials with reducibility.

13. A display panel comprising a thin film transistor, the thin film transistor comprising:
a substrate;
a source electrode, disposed on a side of the substrate;
an interlayer insulating layer, disposed on a side of the source electrode away from the substrate and exposing a part of the source electrode;
a first gate electrode, disposed on a side of the interlayer insulating layer away from the substrate;
a first gate insulating layer, disposed on a side of the first gate electrode away from the substrate and covering on a sidewall of the first gate electrode;
a drain electrode, disposed on a side of the first gate insulating layer away from the substrate;
an active layer, disposed on a side of the first gate insulating layer away from the first gate electrode and covering on the sidewall of the drain electrode, the sidewall of the first gate insulating layer, and the source electrode exposed by the interlayer insulating layer, wherein the active layer comprises at least two semiconductor layers stacked;
wherein conductivity types of channel regions of adjacent two of the semiconductor layers are same, and doping concentrations of same elements in semiconductor materials of the adjacent two of the semiconductor layers are different.

14. The display panel according to claim 13, wherein the active layer comprises a first semiconductor layer and a second semiconductor layer stacked, and band gaps of the first semiconductor layer and the second semiconductor layer are different.

15. The display panel according to claim 13, wherein the active layer comprises a first semiconductor layer and a second semiconductor layer stacked, a material of the first semiconductor layer is indium zinc oxide (IZO), a material of the second semiconductor layer is indium gallium zinc oxide (IGZO), and a doping concentration of indium element in the first semiconductor layer is different from a doping concentration of indium element in the second semiconductor layer.

16. The display panel according to claim 13, wherein the active layer comprises a first semiconductor layer and a second semiconductor layer stacked, both materials of the first semiconductor layer and the second semiconductor layer are IGZO, and a doping concentration of indium element in the first semiconductor layer is different from a doping concentration of indium element in the second semiconductor layer.

17. The display panel according to claim 16, wherein a thickness of the first semiconductor layer is less than a thickness of the second semiconductor layer.

18. The display panel according to claim 16, wherein the active layer further comprises a third semiconductor layer located on a side of the second semiconductor layer away from the first semiconductor layer, a material of the third semiconductor layer is IGZO, and a doping concentration of indium element in the third semiconductor layer is different from the doping concentration of the indium element in the second semiconductor layer.

19. The display panel according to claim 18, wherein the doping concentration of indium element in the second semiconductor layer is greater than the doping concentration of indium element in the third semiconductor layer.

20. The display panel according to claim 13, wherein the active layer comprises a first semiconductor layer and a second semiconductor layer stacked and a third semiconductor layer located on a side of the second semiconductor layer away from the first semiconductor layer, band gaps of the third semiconductor layer and the second semiconductor layer are different, and materials of the first semiconductor layer, the second semiconductor lay
